(19) United States
(12) Patent Application Publication
(10) Pub. No.: US 2009/0323419 A1
(43) Pub. Date: Dec. 31, 2009

(54) READ-TIME WEAR-LEVELING METHOD IN STORAGE SYSTEM USING FLASH MEMORY DEVICE

(75) Inventors: Joo-Hyeong Lee, Seoul (KR); Ki-Yeong Shin, Seoul (KR)

Correspondence Address: MCDERMOTT WILL & EMERY LLP, 600 13TH STREET, N.W., WASHINGTON, DC, 20005-3096, US

(73) Assignee: SDC MICRO INC.

(21) Appl. No.: 12/492,696

(22) Filed: Jun. 26, 2009

(30) Foreign Application Priority Data
Jun. 26, 2008 (KR) 10-2008-0061220

(51) Int. Cl. G11C 16/04

(52) U.S. Cl. 365/185.11; 365/185.18

(57) ABSTRACT

Disclosed is a read-time wear-leveling method in a storage system using a flash memory device, in which the abrasion of the flash memory device generated by repeated read operations is dispersed over the entire region so that the abrasion of memory blocks can be equalized to prolong the life of the flash memory device, to minimize errors in the memory blocks, and to secure the reliability of the storage system.

### BACKGROUND OF THE INVENTION

1. Field of the Invention

The present invention relates to a read-time wear-leveling method in a storage system using a flash memory device, and more particularly to, a read-time wear-leveling method in a storage system using a flash memory device, in which the abrasion of a flash memory device caused by repeated read operations is dispersed over the entire region so that the abrasion equalization of memory blocks can be maintained to prolong the life of the flash memory device, to minimize errors in the memory blocks, and to secure the reliability of the storage system.

2. Description of the Related Art

A flash memory device is a non-volatile memory device having low power consumption and a characteristic in that stored information is not lost although power is intercepted. In particular, it is well-known that, since information is freely input to and output from the flash memory device, the flash memory device is widely used for a digital television, a digital camcorder, a mobile telephone, a digital camera, a personal digital assistant (PDA), an electronic game, and an MP3 player. The flash memory device is classified into a data storage type NAND flash memory device having large storage capacity and a code storage type NOR flash memory device having rapid processing speed.

In the flash memory device, the NAND flash device that is currently commercially used a lot commonly has limitations on the number of times of repeating write/erase operations of about 10,000 to 100,000 per block (the minimum operation unit when the flash memory device is driven). In particular, although there are slight differences among manufacturing companies, a higher density multi-level-cell (MLC) NAND flash device that stores 2 bits per cell commonly supports the number of times of repeating operations of 10,000 per block.

The number of times of repeating operations of the flash memory device causes the abrasion of the NAND flash cell that repeatedly performs the write/delete operations. Therefore, a technology of equalizing the abrasion in the entire region to prolong the life of the flash memory device is suggested and performed. In this case, the technology of equalizing the abrasion is mainly applied only to the write/erase operations.

However, the repeated operations of the flash memory device include a process of performing a read operation other than the write/erase operations. In the case of an application such as a paging file system, in which the read operation is to be performed on the partial region of a memory array at a high frequency in the read operation, the life of the flash memory device is remarkably reduced in accordance with the partial abrasion of a memory cell.

In addition, due to the abrasion, the memory blocks generate frequent errors so that the reliability of the flash memory device that is a storage system is poor.

### BRIEF SUMMARY OF THE INVENTION

The present invention has been made in view of the above problems, and the present invention provides a read-time wear-leveling method in which the abrasion of a flash memory device caused by repeatedly performing read operations on data stored in the flash memory device is dispersed over the entire region so that the abrasion of memory blocks can be equalized to prolong the life of the flash memory device and to minimize operation errors in the memory blocks.

In accordance with an embodiment of the present invention, a read-time wear-leveling method in a storage system using a flash memory device includes: counting the number of times of read operations on addresses of respective physical memory blocks assigned to a memory; storing the counted number of times of read operations in a control memory block of the memory and, dispersing abrasion caused by the read operations by copying the content of the logic memory block to a new physical memory block by a logic memory block as a read-time wear-leveling block when the number of times of read operations reaches a set threshold; and updating an address table of the logic memory block.

At this time, the memory counts only the read operations or counts the read operations by adding write/erase operations. In particular, the counted number of times of operations is stored in a separate memory. In addition, the operations generated in the memory are repeatedly performed equal to or higher than 2 times so that the number of times of operations is uniformly distributed over an entire memory array.

As described above, according to the present invention, the abrasion of a logic memory block, which is generated during the read operation of a flash memory device, is divisionally mapped to a physical memory block so that the abrasion is equalized over the entire memory block and that the life of the flash memory device can be prolonged.

In addition, according to the present invention, since the abrasion of the flash memory device is equalized, the operation errors of the flash memory device caused by partial abrasion can be reduced so that the reliability of the flash memory device can be improved.

### BRIEF DESCRIPTION OF THE DRAWINGS

The objects, features and advantages of the present invention will be more apparent from the following detailed description in conjunction with the accompanying drawings, in which:

FIG. 1 is a block diagram illustrating performance of a read-time wear-leveling method according to an embodiment of the present invention; and

FIG. 2 is a flowchart illustrating processes of performing the read-time wear-leveling method according to the embodiment of the present invention.

### DETAILED DESCRIPTION OF THE INVENTION

Hereinafter, an embodiment of the present invention will be described in detail with reference to the accompanying drawings.

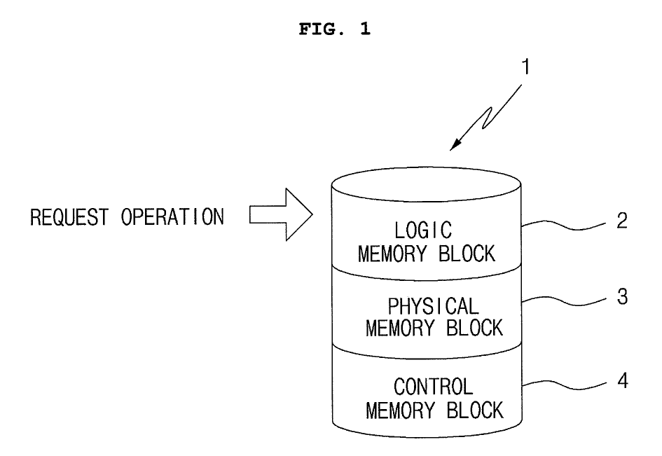

FIG. 1 is a block diagram illustrating performance of a read-time wear-leveling method according to an embodiment of the present invention.

Referring to the drawing, in order to perform read-time wear-leveling according to an embodiment of the present invention, a memory cell 1 is divided into a logic memory block 2, a physical memory block 3, and a control memory block 4.

The memory cell 1 becomes a space in which the respective memory blocks 2, 3, and 4 exist and various processors such as a central processing unit (CPU) operating a memory are connected to the memory cell 1. In addition, the number of each block is only one in the drawing. However, it is well-known that each block may be divided into a plurality of regions no less than 2 and that addresses may be assigned to the divided blocks, respectively.

The logic memory block 2 is a memory region in which operations are performed in real time. At this time, the operations include write/erase and read operations.

The physical memory block 3 is a memory region in which operations are not currently performed in a standby state. In particular, after a process of counting the number of times of operations and a leveling process performed by the logic memory block 2 to be described later, when a data table is updated, the logic memory block 2 is changed to have the data table state of the physical memory block 3.

The control memory block 4 is a memory region in which Meta data on operating a flash memory device and counting the number of times of operations are previously stored or stored in real time.

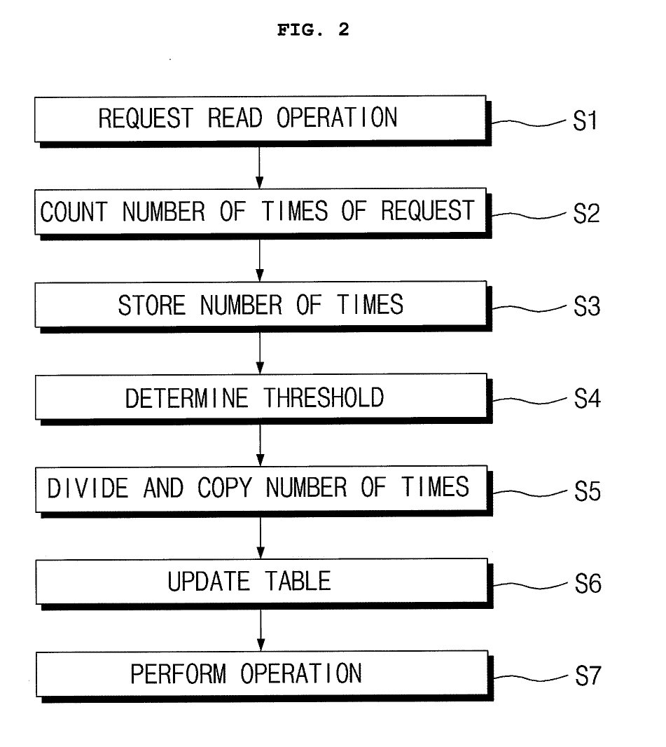

FIG. 2 is a flowchart illustrating processes of performing the read-time wear-leveling method according to the embodiment of the present invention.

Referring to the drawing, in the leveling process, when the write/erase and read operations, in particular, the read operation are requested by the user of the flash memory device, the number of times of request is counted (S1 and S2). At this time, the number of times of request is “a previously counted coefficient value +1”.

Then, the counted number of times is stored in the control memory block 4 (S3). The control memory block 4 compares the stored counted number of times with a previously set threshold (a threshold for the number of times of operations) to determined processes after that (S4). The counted number of times is additionally stored in a separated external memory so that the leveling process can be performed on a plurality of flash memory devices.

The determination is a process of determining whether the operations are continuously performed by the currently used logic memory block 2 or whether the operations requested by the logic memory block 2 are distributed to the physical memory block 3. That is, when the counted number of times is smaller than the threshold, the logic memory block 2 continuously performs the operations. At the point of time when the counted number of times is equal to the threshold, the operations requested by the logic memory block 2 are distributed to the physical memory block 3.

In order to distribute the requested operations, as a result of determination, from the logic memory block 2 to the physical memory block 3, the logic memory block 2 that is a read-time wear-leveling block copies the content of the block to a new physical memory block 3 (S5).

Then, in the logic memory block 2, the address table of the memory region is updated since a read-time wear-leveling source is copied to the new physical memory block 3 (S6). At the same time, the control memory block 4 performs the operations requested by the user (S7).

By performing the above-described processes, the partial abrasion generated by performing the operations only in the memory region of a specific address is distributed to the entire region of a memory array so that the life of the flash memory device may be prolonged and that stable memory operations may be performed.

The above processes were described based on the case in which the read operation is requested. However, the leveling process may be performed by counting the number of times of read operations together with write/erase operations or by counting the number of times of read operations only.

Although exemplary embodiments of the present invention have been described in detail hereinabove, it should be understood that many variations and modifications of the basic inventive concept herein described, which may appear to those skilled in the art, will still fall within the spirit and scope of the exemplary embodiments of the present invention as defined by the appended claims.

What is claimed is:

1. A read-time wear-leveling method in a storage system using a flash memory device, comprising:
counting the number of times of read operations on addresses of respective physical memory blocks assigned to a memory;
storing the counted number of times of read operations in a control memory block of the memory and, dispersing abrasion caused by the read operations by copying the content of the logic memory block to a new physical memory block by a logic memory block as a read-time wear-leveling block when the number of times of read operations reaches a set threshold; and
updating an address table of the logic memory block.

2. The read-time wear-leveling method of claim 1, wherein the memory counts only the read operations or counts the read operations by adding write/erase operations.

3. The read-time wear-leveling method of claim 2, wherein the counted number of times of operations is stored in a separate memory.

4. The read-time wear-leveling method of any one of claims 1 to 3, wherein the operations generated in the memory are repeatedly performed equal to or higher than 2 times so that the number of times of operations is uniformly distributed over an entire memory array.
